(19) United States
(12) Patent Application Publication
(10) Pub. No.: US 2025/0174535 A1
(43) Pub. Date: May 29, 2025

(54) WIRING SUBSTRATE AND SEMICONDUCTOR PACKAGE INCLUDING THE SAME

(71) Applicant: Samsung Electronics Co., Ltd., Suwon-si (KR)

(72) Inventors: Heewoo AN, Suwon-si (KR); Sang Sub SONG, Suwon-si (KR)

(73) Assignee: Samsung Electronics Co., Ltd., Suwon-si (KR)

(21) Appl. No.: 18/753,548

(22) Filed: Jun. 25, 2024

(30) Foreign Application Priority Data
Nov. 28, 2023 (KR) 10-2023-0167816
Jan. 11, 2024 (KR) 10-2024-0004770

(51) Int. Cl. H01L 23/498; H01L 23/00

(52) U.S. Cl. CPC H01L 23/49822; H01L 23/49816; H01L 23/49838; H01L 24/06; H01L 24/08; H01L 24/13; H01L 24/16; H01L 2224/06131; H01L 2224/0801; H01L 2224/08056; H01L 2224/08237; H01L 2224/13023; H01L 2224/16227; H01L 2924/3025

(57) ABSTRACT

A wiring substrate may include a power pattern in a first insulating pattern in a first substrate wiring layer, a second substrate wiring layer on the first substrate wiring layer and including a first ground pattern in a second insulating pattern, a third substrate wiring layer on the second substrate wiring layer and including a first signal pattern in a third insulating pattern, and a pad layer a bottom surface of the first substrate wiring layer. The pad layer may include signal pads and a ground pad in the protection layer. The ground pad may be between the signal pads. The power pattern may vertically overlap the ground pad. The first ground pattern may vertically overlap the ground pad and the power pattern. The first signal pattern may be on the first ground pattern.

### CROSS-REFERENCE TO RELATED APPLICATIONS

This U.S. non-provisional patent application claims priority under 35 U.S.C. § 119 to Korean Patent Application Nos. 10-2023-0167816 and 10-2024-0004770, filed on Nov. 28, 2023 and Jan. 11, 2024, respectively, in the Korean Intellectual Property Office, the entire contents of which are hereby incorporated by reference.

### BACKGROUND

The present disclosure relates to a wiring substrate and a semiconductor package including the same.

With recent advances in the electronics industry, the demand for high-performance, high-speed, and compact electronic components may be increasing. To meet this demand, packaging technologies of mounting a plurality of semiconductor chips in a single package are being developed.

Recently, the demand for portable electronic devices has been rapidly increasing in the market, and thus, it may be necessary to reduce sizes and weights of electronic components constituting the portable electronic devices. In order to achieve this, it may be necessary to develop packaging technologies of reducing a size and a weight of each component and of integrating a plurality of individual components in a single package. In the case of a semiconductor package in which multiple devices are integrated, there may be a need to reduce the size of the semiconductor package and improve the heat-emission and electrical characteristics of the semiconductor package.

Multiple semiconductor chips and multiple semiconductor devices may be mounted on a printed circuit board. However, as the operation speed of the semiconductor chip increases, the influence of a cross talk issue between signals on the signal integrity may increase. In addition, there may be an electromagnetic interference (EMI) issue between the semiconductor chips. The EMI issue may lead to malfunction of semiconductor chips and semiconductor devices which are adjacent to each other.

### SUMMARY

An embodiment of inventive concepts provides a wiring substrate with improved electrical characteristics and a semiconductor package including the same.

According to an embodiment of inventive concepts, a wiring substrate may include a first substrate wiring layer including a first insulating pattern and a power pattern in the first insulating pattern; a second substrate wiring layer on the first substrate wiring layer, the second substrate wiring layer including a second insulating pattern and a first ground pattern in the second insulating pattern; a third substrate wiring layer on the second substrate wiring layer, the third substrate wiring layer including a third insulating pattern and a first signal pattern in the third insulating pattern; and a pad layer covering a bottom surface of the first substrate wiring layer, the pad layer including a protection layer and the pad layer including signal pads and a ground pad in the protection layer. The ground pad may be between the signal pads. The power pattern may vertically overlap the ground pad. The first ground pattern may vertically overlap the ground pad and the power pattern. The first signal pattern may be on the first ground pattern.

According to an embodiment of inventive concepts, a wiring substrate may include a body layer; a ground pad and signal pads on a bottom surface of the body layer; a first substrate wiring layer in the body layer; and a second substrate wiring layer in the body layer and on the first substrate wiring layer. The first substrate wiring layer may include first signal patterns and a power pattern. The power pattern may be placed between the first signal patterns, when viewed in a plan view. The power pattern may be placed on the ground pad. The second substrate wiring layer may include a second signal pattern. The second signal pattern may be on the power pattern.

According to an embodiment of inventive concepts, a semiconductor package may include a substrate; a semiconductor chip on the substrate; and a mold layer on the substrate and enclosing the semiconductor chip. The substrate may include a body layer, a ground pad and signal pads on a bottom surface of the body layer, a first signal pattern in the body layer, and a power pattern in the body layer. The power pattern may be between the ground pad and the first signal pattern. The power pattern may be on the ground pad. The first signal pattern may be on the power pattern. On the ground pad, a horizontal width of the power pattern may be 0.8 to 1.2 times a horizontal width of the ground pad.

### BRIEF DESCRIPTION OF THE DRAWINGS

FIG. 1 is a sectional view illustrating a wiring substrate according to an embodiment of inventive concepts.

FIG. 2 is a plan view illustrating a wiring substrate according to an embodiment of inventive concepts.

FIGS. 3 and 4 are enlarged sectional views illustrating a portion ‘A’ of FIG. 1.

FIG. 5 is a sectional view illustrating a wiring substrate according to an embodiment of inventive concepts.

FIG. 6 is an enlarged sectional view illustrating a portion ‘B’ of FIG. 5.

FIG. 7 is a sectional view illustrating a wiring substrate according to an embodiment of inventive concepts.

FIG. 8 is an enlarged sectional view illustrating a portion ‘C’ of FIG. 7.

FIG. 9 is a sectional view illustrating a wiring substrate according to an embodiment of inventive concepts.

FIGS. 10 and 11 are sectional views illustrating a semiconductor package according to an embodiment of inventive concepts.

### DETAILED DESCRIPTION

Example embodiments of inventive concepts will now be described more fully with reference to the accompanying drawings, in which example embodiments are shown. Like reference numerals in the drawings denote like elements, and thus their description will be omitted. It will be understood that when an element or layer is referred to as being “on” or “above” another element or layer, it may be directly on another element or layer or other element or layer may be interposed therebetween.

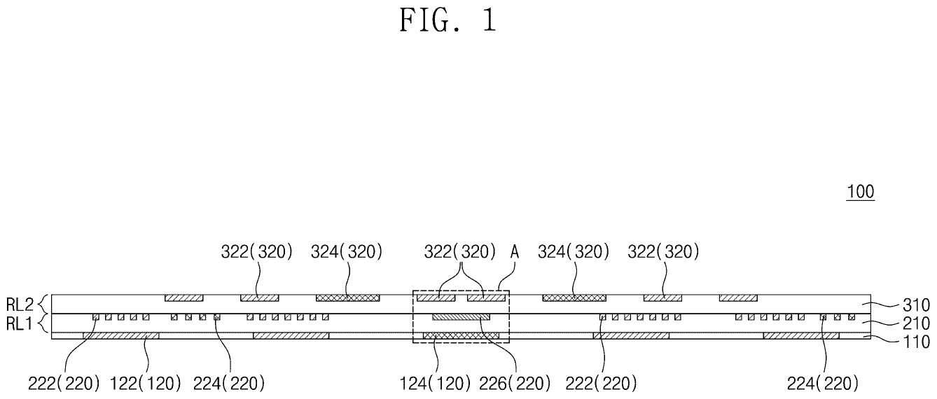

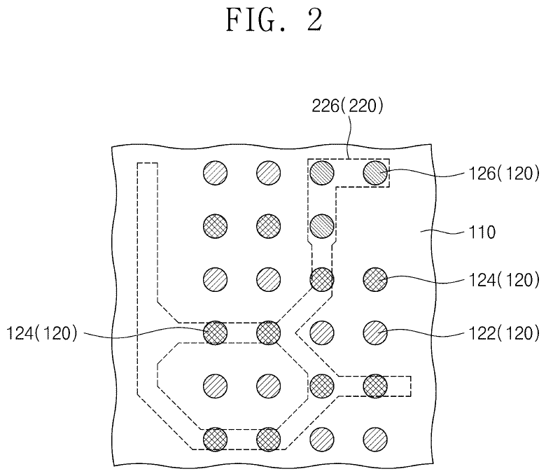

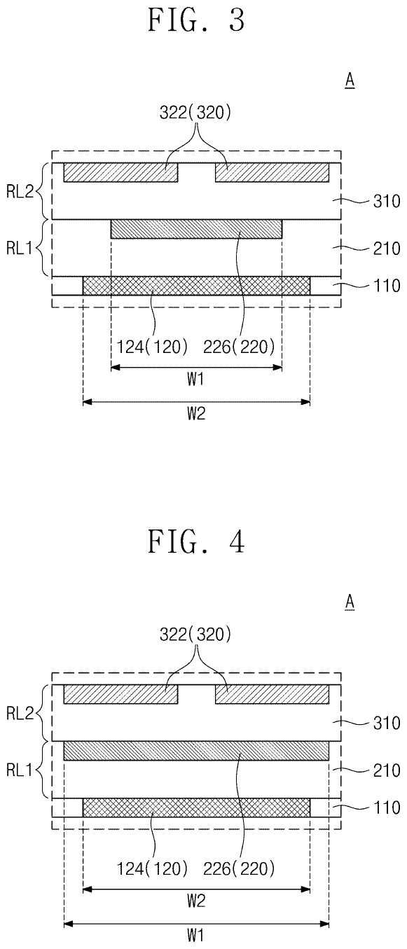

FIG. 1 is a sectional view illustrating a wiring substrate according to an embodiment of inventive concepts. FIG. 2 is a plan view illustrating a wiring substrate (e.g., a substrate protection layer and substrate pads of the wiring substrate) according to an embodiment of inventive concepts. Furthermore, a first power pattern of a first substrate wiring layer is also illustrated in FIG. 2. FIGS. 3 and 4 are enlarged sectional views illustrating a portion ‘A’ of FIG. 1. FIGS. 1 and 2 illustrate one example of possible placements and shapes of the substrate pads and conductive patterns, which are prepared for convenience in description, but inventive concepts are not limited to this example.

Referring to FIGS. 1 to 3, a wiring substrate 100 may be provided. The wiring substrate 100 may be a printed circuit board (PCB). However, inventive concepts are not limited to this example, and various substrates including a redistribution substrate may be used as the wiring substrate 100.

The wiring substrate 100 may have a structure including an insulating layer and a plurality of wiring patterns provided in the insulating layer. For example, the wiring substrate 100 may have a structure, in which insulating patterns and wiring patterns are alternately stacked. In detail, the wiring substrate 100 may include a substrate protection layer 110 and at least two substrate wiring layers RL1 and RL2, which are stacked on the substrate protection layer 110.

The substrate protection layer 110 may include an insulating material. For example, the substrate protection layer 110 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers.

Substrate pads 120 may be provided in the substrate protection layer 110 and may be electrically connected to the substrate wiring layers RL1 and RL2, which are placed on the substrate protection layer 110. The substrate pads 120 may be buried in the substrate protection layer 110. The substrate pads 120 may be exposed to the outside of the substrate protection layer 110 through top and bottom surfaces of the substrate protection layer 110. Bottom surfaces of the substrate pads 120 may be coplanar with the bottom surface of the substrate protection layer 110. Unlike the illustrated structure, the substrate pads 120 may be placed on the bottom surface of the substrate protection layer 110 and may protrude relative to the bottom surface of the substrate protection layer 110. Solder balls or the like, which are used to mount the wiring substrate 100 on another device or another substrate, may be coupled to the substrate pads 120. The substrate pads 120 may include a conductive material. For example, the substrate pads 120 may be formed of or include copper (Cu).

Although not shown, each of the substrate pads 120 may include a seed layer or a barrier layer, which is provided to cover bottom and side surfaces of the substrate pad 120. In an embodiment, the seed layer or the barrier layer may be provided on only the bottom surface of the substrate pad 120. The substrate protection layer 110 and the substrate pads 120 may constitute a pad layer of the wiring substrate 100.

As shown in FIG. 2, the substrate pads 120 may include signal pads 122, ground pads 124, and power pads 126. The signal pads 122 may be used to input and output operation signals to and from a semiconductor chip, which is mounted on the wiring substrate 100. The ground pads 124 may be used to apply a ground signal to the wiring substrate 100 and the semiconductor chip thereon. The power pads 126 may be used to supply an electric power to the semiconductor chip on the wiring substrate 100. The signal and ground pads 122 and 124 may be provided throughout the substrate protection layer 110. As an example, the signal and ground pads 122 and 124 may be provided on a center region of the substrate protection layer 110 and may also be provided on an edge region of the substrate protection layer 110 enclosing the center region. At least some of the ground pads 124 may be located between the signal pads 122. For example, the at least some of the ground pads 124 may be provided on the center region of the substrate protection layer 110. The power pads 126 may be disposed in a region adjacent to a side surface of the substrate protection layer 110. As an example, the power pads 126 may be placed on the edge region of the substrate protection layer 110. The power pads 126 may be placed between the signal and ground pads 122 and 124 and the side surface of the substrate protection layer 110.

The substrate wiring layers RL1 and RL2 may be stacked on the substrate protection layer 110. In the present specification, the substrate wiring layer may mean the substrate wiring layer of the wiring substrate 100, which is formed by patterning one insulating layer and one conductive layer, respectively. That is, conductive patterns in the substrate wiring layer RL1 or RL2 may be wiring lines, which are horizontally extended and are not vertically overlapped with each other. Each of the substrate wiring layers RL1 and RL2 may include an insulating pattern 210 or 310 and conductive patterns 220 or 320, which are provided in the insulating pattern 210 or 310. The conductive patterns 220 or 320 in one of the substrate wiring layers RL1 and RL2 may be electrically connected to the conductive patterns 220 or 320 in another one of the substrate wiring layers RL1 and RL2. Hereinafter, the schematic structure of the substrate wiring layers RL1 and RL2 will be described in more detail with reference to a first substrate wiring layer RL1, which is placed on the substrate protection layer 110.

The first substrate wiring layer RL1 may include a first insulating pattern 210 and first conductive patterns 220 in the first insulating pattern 210.

The first insulating pattern 210 may be formed of or include an inorganic insulating material (e.g., silicon oxide (SiOₓ) or silicon nitride (SiNₓ)). In an embodiment, the first insulating pattern 210 may be formed of or include at least one polymeric material. The first insulating pattern 210 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers.

The first conductive patterns 220 may be provided in the first insulating pattern 210. The first conductive patterns 220 may be exposed to the outside of the first insulating pattern 210 near a top surface of the first insulating pattern 210. The first conductive patterns 220 may be covered with a second insulating pattern 310 of a second substrate wiring layer RL2. The first conductive patterns 220 may be horizontally extended, in the first insulating pattern 210. As described above, each of the first conductive patterns 220 may be a pad portion or a wire portion of the first substrate wiring layer RL1. That is, the first conductive patterns 220 may be used for horizontal redistribution in the wiring substrate 100. Unlike the illustrated structure, the first conductive patterns 220 may be disposed on the top surface of the first insulating pattern 210. The first conductive patterns 220 may protrude upward relative to the top surface of the first insulating pattern 210. The first conductive patterns 220 may include a conductive material. For example, the first conductive patterns 220 may be formed of or include copper (Cu).

Although not shown, at least a portion of the first conductive pattern 220 may include a via pattern, which is extended from a bottom surface thereof and has a downward protruding shape. The via pattern may be used to connect the first conductive pattern 220 to the substrate pad 120. For example, the via pattern may be extended from the bottom surface of the first conductive pattern 220 to penetrate the first insulating pattern 210 and may be coupled to a top surface of the substrate pad 120. The portion of the first conductive pattern 220 may have a ‘T’-shaped section.

The first conductive patterns 220 may include first signal patterns 222, first ground patterns 224, and a first power pattern 226. The first signal patterns 222, the first ground patterns 224, and the first power pattern 226 may be located at the same vertical level.

The first signal patterns 222 and the first ground patterns 224 may include line patterns. In other words, the first signal patterns 222 may be composed of a plurality of wiring lines, which are horizontally extended in the first insulating pattern 210, and the first ground patterns 224 may be composed of a plurality of wiring lines, which are horizontally extended in the first insulating pattern 210. The first signal patterns 222 may be electrically connected to the signal pads 122. The first ground patterns 224 may be electrically connected to the ground pads 124.

The first power pattern 226 may be a single pattern. For example, the first power pattern 226 may be a network pattern, which is formed by a plurality of wiring lines that are horizontally extended in the first insulating pattern 210 and are connected to each other. The first power pattern 226 may be electrically connected to the power pads 126. For example, the first power pattern 226 may be placed on the power pads 126. At least a portion of the first power pattern 226 may be placed on the center region of the substrate protection layer 110. The first power pattern 226 may be extended to regions, which are placed on at least some of the ground pads 124. The first power pattern 226 may not be extended to regions, which are placed on the signal pads 122. That is, the first power pattern 226 may be vertically overlapped with at least some of the ground pads 124. The first power pattern 226 may not be vertically overlapped with the signal pads 122 and may be spaced apart from the signal pads 122, when viewed in a plan view. That is, the first power pattern 226 may be positioned between the signal pads 122. The first power pattern 226 may pass through regions between the first signal patterns 222 or between the first ground patterns 224.

FIGS. 3 and 4 are vertical sections illustrating regions where the first power pattern 226 and the ground pad 124 are overlapped with each other. The description that follows will refer to a section, in which one of the ground pads 124 and the first power pattern 226 placed thereon are included. The first power pattern 226 may be disposed on the ground pad 124. When viewed in a plan view, the first power pattern 226 may be provided to completely cross the ground pad 124. The first power pattern 226 may pass through a region on a center portion of the ground pad 124. Here, as shown in FIG. 3, a first width W1 of the first power pattern 226 may be smaller than a second width W2 of the ground pad 124. Here, the first width W1 of the first power pattern 226 and the second width W2 of the ground pad 124 may be measured on the ground pad 124 in a direction parallel to a top surface of the ground pad 124. For example, when viewed in the width direction of the first power pattern 226 crossing the ground pad 124, side surfaces of the first power pattern 226 may be placed on the ground pad 124. Alternatively, as shown in FIG. 4, the first width W1 of the first power pattern 226 may be equal to or larger than the second width W2 of the ground pad 124. For example, the entirety of the ground pad 124 may be placed below the first power pattern 226. Referring to FIGS. 3 and 4, the first width W1 of the first power pattern 226 may be similar to or smaller than the second width W2 of the ground pad 124. The first width W1 of the first power pattern 226 may be 0.8 to 1.2 times the second width W2 of the ground pad 124.

The first power pattern 226 may be vertically spaced apart from the ground pad 124 by the first insulating pattern 210. The first power pattern 226 and the ground pad 124 may form a microstrip structure.

In an embodiment, when viewed in a plan view, the first power pattern 226 may pass through regions, which are located on the ground pads 124 and between the signal pads 122. In this case, the first power pattern 226 and the ground pads 124 may form a microstrip structure, and thus, an interference signal (e.g., a noise signal), which is generated from the first power pattern 226, may be absorbed by the ground pads 124. Thus, the interference signal, which is generated from the first power pattern 226, may not affect the signal pads 122 or other patterns (e.g., the first signal patterns 222) in the first substrate wiring layer RL1. That is, the wiring substrate and the semiconductor package therewith may have improved electrical characteristics.

Referring to FIGS. 1 to 3, the second substrate wiring layer RL2 may include the second insulating pattern 310 and second conductive patterns 320, which are provided in the second insulating pattern 310.

The second insulating pattern 310 may be formed of or include an inorganic insulating material (e.g., silicon oxide (SiOₓ) or silicon nitride (SiNₓ)). Alternatively, the second insulating pattern 310 may be formed of or include at least one of polymeric materials. The second insulating pattern 310 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers. The second insulating pattern 310 may cover the first substrate wiring layer RL1. In an embodiment, the second insulating pattern 310 may be provided on the first insulating pattern 210 to cover the first conductive patterns 220. The first and second insulating patterns 210 and 310 may constitute a body layer of the wiring substrate 100. As an example, the first and second insulating patterns 210 and 310 may be formed of the same material and may be provided as a layer made of a single material.

The second conductive patterns 320 may be provided in the second insulating pattern 310. The second conductive patterns 320 may be exposed to the outside of the second insulating pattern 310 near the top surface of the second insulating pattern 310. The second conductive patterns 320 may be horizontally extended, in the second insulating pattern 310. As described above, each of the second conductive patterns 320 may be a pad portion or a wire portion of the second substrate wiring layer RL2. In other words, the second conductive patterns 320 may be used for horizontal redistribution in the wiring substrate 100. Unlike the illustrated structure, the second conductive patterns 320 may be disposed on the top surface of the second insulating pattern 310. The second conductive patterns 320 may protrude upward relative to the top surface of the second insulating pattern 310. The second conductive patterns 320 may include a conductive material. For example, the second conductive patterns 320 may be formed of or include copper (Cu).

Although not shown, at least a portion of the second conductive pattern 320 may include a via pattern, which is extended from a bottom surface thereof and has a downward protruding shape. The via pattern may be used to connect the second conductive pattern 320 to the first conductive pattern 220 of the first substrate wiring layer RL1. For example, the via pattern may be extended from the bottom surface of the second conductive pattern 320 to penetrate the second insulating pattern 310 and may be coupled to a top surface of the first conductive pattern 220. The portion of the second conductive pattern 320 may have a ‘T’-shaped section.

The second conductive patterns 320 may have second signal patterns 322 and second ground patterns 324. Although not shown, the second conductive patterns 320 may further include a second power pattern. The second signal patterns 322, the second ground patterns 324, and the second power pattern may be located at the same vertical level.

The second signal patterns 322 and the second ground patterns 324 may include line patterns. For example, the second signal patterns 322 may be composed of a plurality of wiring lines, which are horizontally extended in the second insulating pattern 310, and the second ground patterns 324 may be composed of a plurality of wiring lines, which are horizontally extended in the second insulating pattern 310. The power pattern may be composed of a plurality of wiring lines, which are horizontally extended in the second insulating pattern 310. The second signal patterns 322 may be electrically connected to the first signal patterns 222. The second ground patterns 324 may be electrically connected to the first ground patterns 224. The power pattern may be electrically connected to the first power pattern 226.

At least a portion of the second signal pattern 322 may be placed on the first power pattern 226. The description that follows will refer to the second signal patterns 322, which are placed on the first power pattern 226. The second signal patterns 322 may be vertically overlapped with the first power pattern 226. Here, as shown in FIG. 3, at least a portion of each of the second signal patterns 322 may be vertically overlapped with the first power pattern 226. Alternatively, as shown in FIG. 4, the entirety of the second signal patterns 322 may be vertically overlapped with the first power pattern 226.

According to an embodiment of inventive concepts, even when the second signal patterns 322 are placed on the first power pattern 226, the ground pads 124 may absorb the interference signal, which is generated in the first power pattern 226, and thus, the second signal patterns 322 may not be affected by the interference signal. Accordingly, the second signal patterns 322 may be freely disposed regardless of the position of the first power pattern 226. In addition, the first power pattern 226 may be placed in a center region of the wiring substrate 100 without considering the position of the second signal patterns 322. In more detail, even when the first power pattern 226 is disposed to pass through regions between the signal pads 122 or the first signal patterns 222 or to overlap with the second signal patterns 322, the interference signal may not affect operation signals of the signal pads 122, the first signal patterns 222, and the second signal patterns 322. Thus, there may be no need to place the first power pattern 226 in the edge region of the wiring substrate 100 bypassing the signal pads 122, the first signal patterns 222, and the second signal patterns 322. As a result, it may be possible to improve the electrical characteristics of the wiring substrate 100, increase a degree of freedom in disposing wiring patterns the wiring substrate 100, and reduce the sizes of the wiring substrate 100 and the semiconductor package.

referring to FIGS. 1 to 3, the second ground patterns 324 may be placed between the second signal patterns 322. Some of the second signal patterns 322, which are placed on the first power pattern 226, may be located between the second ground patterns 324. The second ground patterns 324 may reduce an intensity of an interference signal propagating toward the second signal patterns 322.

FIG. 1 illustrates an example, in which the second substrate wiring layer RL2 is the uppermost substrate wiring layer of the wiring substrate 100, but inventive concepts are not limited to this example. In an embodiment, the wiring substrate 100 may further include additional substrate wiring layers, which are disposed on the second substrate wiring layer RL2. In the description of the embodiments to be explained below, an element previously described with reference to FIGS. 1 to 4 may be identified by the same reference number without repeating an overlapping description thereof, for concise description.

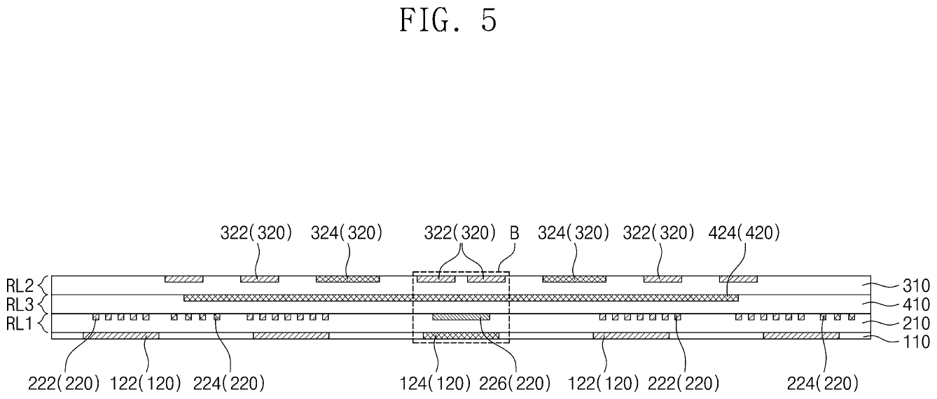

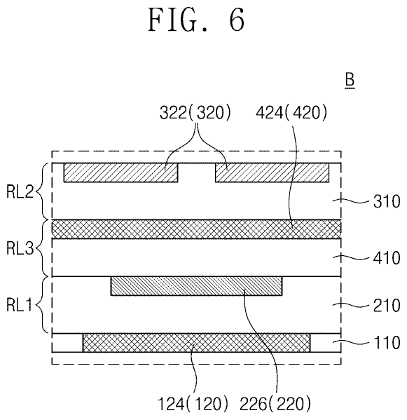

FIG. 5 is a sectional view illustrating a wiring substrate according to an embodiment of inventive concepts. FIG. 6 is an enlarged sectional view illustrating a portion ‘B’ of FIG. 5.

Referring to FIGS. 5 and 6, the wiring substrate may further include a third substrate wiring layer RL3 interposed between the first substrate wiring layer RL1 and the second substrate wiring layer RL2.

The third substrate wiring layer RL3 may include a third insulating pattern 410 and a third conductive pattern 420 in the third insulating pattern 410.

The third insulating pattern 410 may be formed of or include an inorganic insulating material (e.g., silicon oxide (SiOₓ) or silicon nitride (SiNₓ)). In an embodiment, the third insulating pattern 410 may be formed of or include at least one of polymeric materials. The third insulating pattern 410 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers. The third insulating pattern 410 may cover the first substrate wiring layer RL1. In an embodiment, the third insulating pattern 410 may be provided on the first insulating pattern 210 to cover the first conductive patterns 220. The first insulating pattern 210, the second insulating pattern 310, and the third insulating pattern 410 may constitute a body layer of the wiring substrate 100. As an example, the first insulating pattern 210, the second insulating pattern 310, and the third insulating pattern 410 may be formed of the same material and may be provided as a layer made of a single material.

The third conductive patterns 420 may be provided in the third insulating pattern 410. The third conductive patterns 420 may be exposed to the outside of the third insulating pattern 410 near a top surface of the third insulating pattern 410. The third conductive patterns 420 may be horizontally extended, in the third insulating pattern 410. Unlike the illustrated structure, the third conductive patterns 420 may be disposed on the top surface of the third insulating pattern 410. The third conductive patterns 420 may protrude upward relative to the top surface of the third insulating pattern 410. The third conductive patterns 420 may include a conductive material. For example, the third conductive patterns 420 may be formed of or include copper (Cu).

Although not shown, at least a portion of the third conductive pattern 420 may include a via pattern, which is extended from a bottom surface thereof and has a downward protruding shape. The via pattern may be used to connect the third conductive pattern 420 to the first conductive pattern 220 of the first substrate wiring layer RL1. For example, the via pattern may be extended from the bottom surface of the third conductive pattern 420 to penetrate the third insulating pattern 410 and may be coupled to the top surface of the first conductive pattern 220. The third conductive pattern 420 may have a ‘T’-shaped section.

The third conductive patterns 420 may include a third ground pattern 424. Although not shown, the third conductive patterns 420 may further include third signal patterns or a third power pattern. The third signal patterns, the third ground pattern 424, and the third power pattern may be placed at the same vertical level.

The third ground pattern 424 may be a single pattern. For example, the third ground pattern 424 may be a plate-shaped pattern, a line-shaped pattern, or a bar-shaped pattern, which is horizontally extended in the third insulating pattern 410. The third ground pattern 424 may be electrically connected to the first ground patterns 224. The third ground pattern 424 may be disposed between the first power pattern 226 of the first substrate wiring layer RL1 and an at least some of the second signal patterns 322 of the second substrate wiring layer RL2. In more detail, the third ground pattern 424 may be provided on the ground pad 124 to cover the entirety of the first power pattern 226. On the ground pad 124, the entirety of the first power pattern 226 may be vertically overlapped with the third ground pattern 424. A width of the first power pattern 226 may be smaller than a width of the third ground pattern 424. Here, the width of the first power pattern 226 and the width of the third ground pattern 424 may be measured on the ground pad 124 in a direction parallel to the top of the ground pad 124. Some of the second signal patterns 322 may be placed on the third ground pattern 424. All of the second signal patterns 322, which are placed on the first power pattern 226, may be vertically overlapped with the first power pattern 226. That is, the third ground pattern 424 may be provided to pass through regions between the first power pattern 226 and the second signal patterns 322. The third ground pattern 424 may be vertically overlapped with the ground pads 124, which are placed below the first power pattern 226.

The first power pattern 226 may be vertically spaced apart from the ground pad 124 by the first insulating pattern 210. The first power pattern 226 may be vertically spaced apart from the third ground pattern 424 by the third insulating pattern 410. The ground pad 124, the first power pattern 226, and the third ground pattern 424 may form a strip line structure.

In an embodiment, when viewed in a plan view, the first power pattern 226 may be interposed between the ground pads 124 and the third ground pattern 424. In this case, the ground pad 124, the first power pattern 226, and the third ground pattern 424 may form a strip line structure, and thus, an interference signal (e.g., a noise signal), which is generated from the first power pattern 226, may be absorbed by the ground pads 124 or the third ground pattern 424. Thus, the interference signal, which is generated from the first power pattern 226, may not affect the signal pads 122 or other patterns (e.g., the first signal patterns 222) in the first substrate wiring layer RL1. That is, the wiring substrate and the semiconductor package therewith may have improved electrical characteristics.

In addition, since the third ground pattern 424 is interposed between the first power pattern 226 and the second signal patterns 322 on the first power pattern 226, the third ground pattern 424 may be used to block the interference signal, which is generated from the first power pattern 226. Even when the first power pattern 226 is overlapped with the second signal patterns 322, operation signals of the second signal patterns 322 may not be affected by the interference signal.

The second substrate wiring layer RL2 may be disposed on the third substrate wiring layer RL3.

The second insulating pattern 310 may cover the third substrate wiring layer RL3. In an embodiment, the second insulating pattern 310 may be provided on the third insulating pattern 410 to cover the third conductive patterns 420. The first insulating pattern 210, the third insulating pattern 410, and the second insulating pattern 310 may constitute a body layer of the wiring substrate 100. In an embodiment, the first insulating pattern 210, the third insulating pattern 410, and the second insulating pattern 310 may be formed of the same material and may be provided as a layer made of a single material.

The second conductive patterns 320 may be provided in the second insulating pattern 310. The second conductive patterns 320 may be exposed to the outside of the second insulating pattern 310 near the top surface of the second insulating pattern 310.

In the description of the embodiments to be explained below, an element previously described with reference to FIGS. 5 and 6 may be identified by the same reference number without repeating an overlapping description thereof, for concise description.

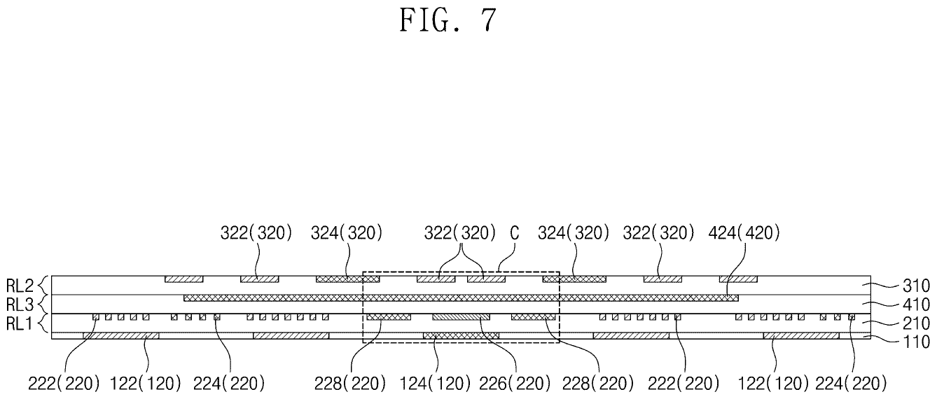

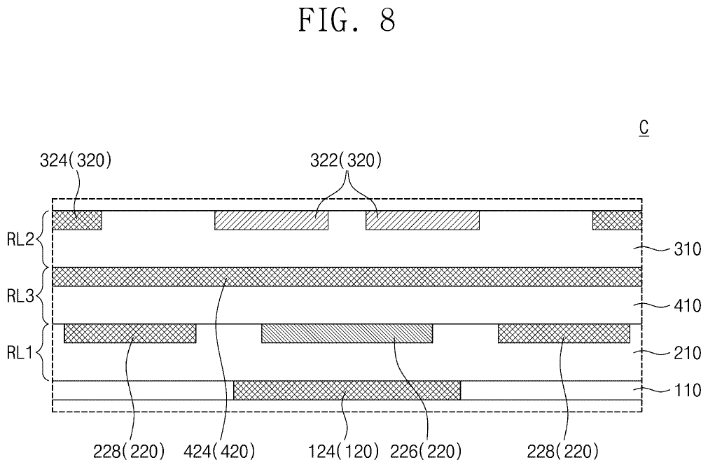

FIG. 7 is a sectional view illustrating a wiring substrate according to an embodiment of inventive concepts. FIG. 8 is an enlarged sectional view illustrating a portion ‘C’ of FIG. 7.

Referring to FIGS. 7 and 8, the first conductive patterns 220 of the first substrate wiring layer RL1 may further include fourth ground patterns 228. The fourth ground patterns 228 may be provided at the same vertical level as the first signal patterns 222, the first ground patterns 224, and the first power pattern 226.

The fourth ground patterns 228 may include line patterns. In an embodiment, the fourth ground patterns 228 may be composed of a plurality of wiring lines, which are provided in the first insulating pattern 210 and are horizontally extended. Alternatively, the fourth ground patterns 228 may be plate-shaped patterns or bar-shaped patterns, which are horizontally extended in the first insulating pattern 210. The fourth ground patterns 228 may be disposed to be adjacent to the first power pattern 226. The fourth ground patterns 228 may be disposed between the first power pattern 226 and the first signal patterns 222. That is, the first signal patterns 222 may be spaced apart from the first power pattern 226, with the fourth ground patterns 228 interposed therebetween. The fourth ground patterns 228 may be horizontally spaced apart from the first power pattern 226. A width of the fourth ground patterns 228 may be larger than a width of the first signal patterns 222 or a width of the first ground patterns 224. The first power pattern 226 may be placed on the ground pads 124 and may be enclosed by the ground pads 124, the fourth ground patterns 228, and the third ground pattern 424.

According to an embodiment of inventive concepts, in the first substrate wiring layer RL1, the first signal patterns 222 may be spaced apart from the first power pattern 226 with the fourth ground patterns 228 interposed therebetween. Thus, the fourth ground patterns 228 may be used to block an interference signal, which is generated from the first power pattern 226. That is, it may be possible to improve the electrical characteristics of the wiring substrate and the semiconductor package.

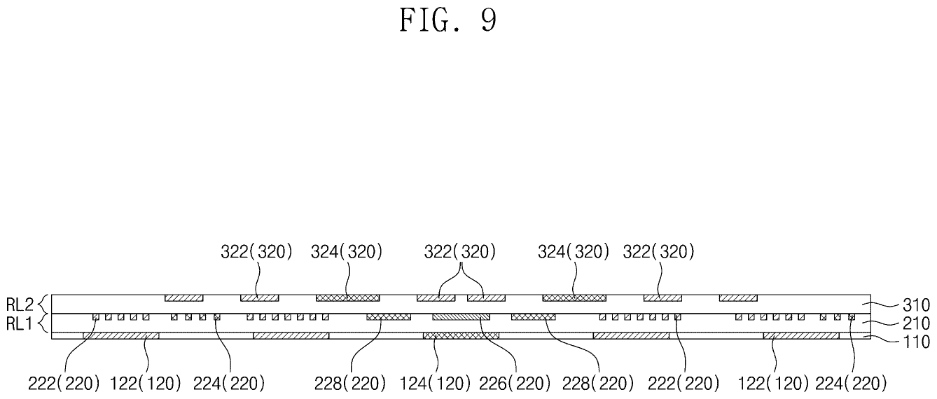

FIG. 9 is a sectional view illustrating a wiring substrate according to an embodiment of inventive concepts.

Referring to FIG. 9, the third substrate wiring layer RL3 may not be provided, unlike the embodiment of FIGS. 7 and 8. That is, the second substrate wiring layer RL2, which includes the second signal patterns 322, the second ground patterns 324, and the second power patterns, may be disposed on the first substrate wiring layer RL1, which includes the first signal patterns 222, the first ground patterns 224, the first power pattern 226, and the fourth ground patterns 228.

The second insulating pattern 310 may cover the first substrate wiring layer RL1. In an embodiment, the second insulating pattern 310 may be provided on the first insulating pattern 210 to cover the first conductive patterns 220. The first and second insulating patterns 210 and 310 may constitute a body layer of the wiring substrate 100. As an example, the first and second insulating patterns 210 and 310 may be formed of the same material and may be provided as a layer made of a single material.

The second conductive patterns 320 may be provided in the second insulating pattern 310. The second conductive patterns 320 may be exposed to the outside of the second insulating pattern 310 near the top surface of the second insulating pattern 310. The second signal patterns 322 may be electrically connected to the first signal patterns 222. The second ground patterns 324 may be electrically connected to the first ground patterns 224 or the fourth ground patterns 228.

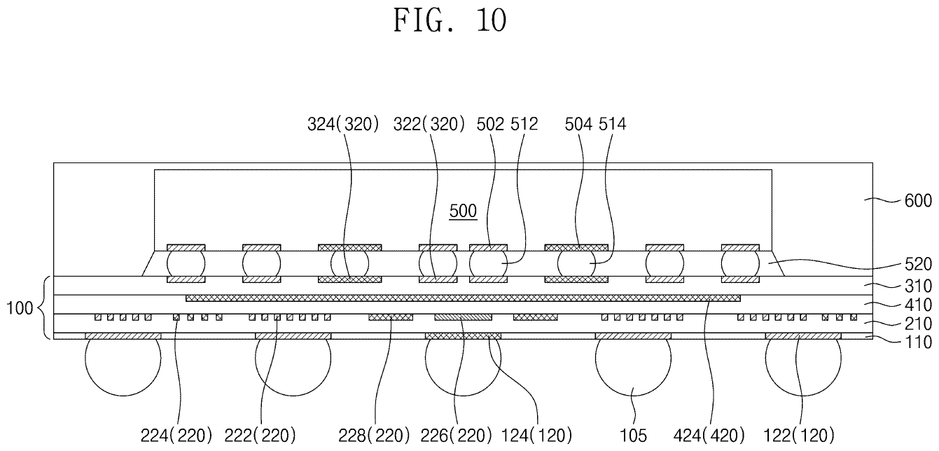

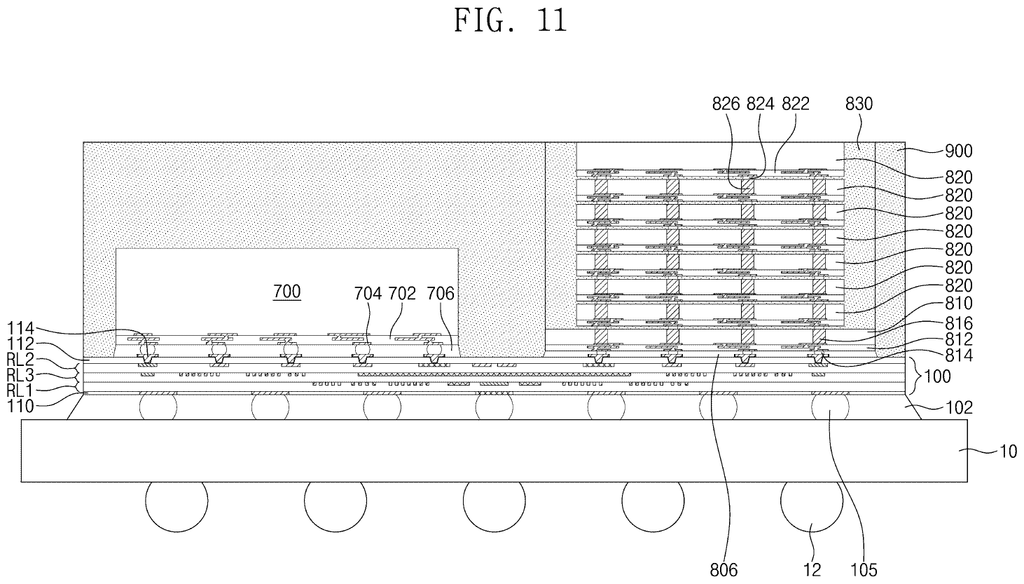

FIG. 10 is a sectional view illustrating a semiconductor package according to an embodiment of inventive concepts.

Referring to FIG. 10, the wiring substrate 100 may be provided. The wiring substrate 100 may have substantially the same or similar structure as the wiring substrate 100 described with reference to FIGS. 1 to 9. In the embodiment of FIG. 10, the wiring substrate of FIG. 7 is illustrated as an example of the wiring substrate 100. For example, the wiring substrate 100 may include the substrate protection layer 110, the substrate pads 120 in the substrate protection layer 110, and a first substrate wiring layer, a third substrate wiring layer, and a second substrate wiring layer, which are stacked on the substrate protection layer 110.

The substrate pads 120 may include the signal pads 122, the ground pads 124, and the power pads 126.

The first substrate wiring layer may include the first insulating pattern 210 and the first conductive patterns 220 in the first insulating pattern 210. The first conductive patterns 220 may include the first signal patterns 222, the first ground patterns 224, the first power pattern 226, and the fourth ground patterns 228. The first power pattern 226 may be located on the ground pads 124. The fourth ground patterns 228 may be disposed near the first power pattern 226. The fourth ground patterns 228 may be placed between the first power pattern 226 and the first signal patterns 222.

The third substrate wiring layer may include the third insulating pattern 410 and the third conductive patterns 420 in the third insulating pattern 410. The third conductive patterns 420 may include the third ground pattern 424. The third ground pattern 424 may be located on the first power pattern 226. The third ground pattern 424 may cover the first power pattern 226.

The second substrate wiring layer may include the second insulating pattern 310 and the second conductive patterns 320 in the second insulating pattern 310. The second conductive patterns 320 may include the second signal patterns 322, the second ground patterns 324, and the second power patterns. At least some of the second signal patterns 322 may be placed on the first power pattern 226. The third ground pattern 424 may be provided to cross a region between the at least some of the second signal patterns 322 and the first power pattern 226. The second conductive patterns 320 of the second substrate wiring layer may be exposed to the outside of the wiring substrate 100 near a top surface of the wiring substrate 100. The second conductive patterns 320 may be used as pads of the wiring substrate 100.

Substrate terminals 105 may be disposed below the wiring substrate 100. In more detail, the substrate terminals 105 may be disposed on the substrate pads 120, which are placed on a bottom surface of the wiring substrate 100. The substrate terminals 105 may include solder balls or solder bumps, and the semiconductor package may be classified into a ball grid array (BGA) package, a fine ball-grid array (FBGA) package, or a land grid array (LGA) package, depending on the type and arrangement of the substrate terminals 105.

A semiconductor chip 500 may be disposed on the wiring substrate 100. The semiconductor chip 500 may include a semiconductor material (e.g., silicon (Si)). The semiconductor chip 500 may include an integrated circuit, which is provided on a surface of the semiconductor chip 500. The integrated circuit of the semiconductor chip 500 may include a logic circuit or a memory circuit. For example, the semiconductor chip 500 may be a logic chip or memory chip. A bottom surface of the semiconductor chip 500 may be an active surface, and a top surface of the semiconductor chip 500 may be an inactive surface. Chip pads 502 and 504 may be disposed on the bottom surface of the semiconductor chip 500, and connection terminals 512 and 514 may be provided on the chip pads 502 and 504. The chip pads 502 and 504 may include first chip pads 502, which are used to deliver driving signals to the integrated circuit in the semiconductor chip 500, and second chip pads 504, which are used to apply ground signals to the integrated circuit. Although not shown, the chip pads 502 and 504 may further include third chip pads, which are used to supply an electric power to the integrated circuit. The connection terminals 512 and 514 may include first connection terminals 512, which are connected to the first chip pads 502, and second connection terminals 514, which are connected to the second chip pads 504. The connection terminals 512 and 514 may be electrically connected to the integrated circuit of the semiconductor chip 500.

The semiconductor chip 500 may be mounted on the wiring substrate 100. For example, the semiconductor chip 500 may be mounted on the wiring substrate 100 in a flip chip manner. The semiconductor chip 500 may be coupled to the second conductive patterns 320 of the wiring substrate 100 through the connection terminals 512 and 514. For example, the first connection terminals 512 may be coupled to the second signal patterns 322, and the second connection terminals 514 may be coupled to the second ground patterns 324. The connection terminals 512 and 514 may be provided between the second conductive patterns 320 of the wiring substrate 100 and the chip pads 502 and 504 of the semiconductor chip 500.

An under-fill layer 520 may be provided between the wiring substrate 100 and the semiconductor chip 500. The under-fill layer 520 may fill a space between the wiring substrate 100 and the semiconductor chip 500 and may enclose the connection terminals 512 and 514.

A mold layer 600 may be provided on the wiring substrate 100. The mold layer 600 may cover the top surface of the wiring substrate 100. The mold layer 600 may be provided to enclose the semiconductor chip 500. The mold layer 600 may include an insulating material. For example, the mold layer 600 may be formed of or include an epoxy molding compound (EMC).

FIG. 11 is a sectional view illustrating a semiconductor package according to an embodiment of inventive concepts.

Referring to FIG. 11, a package substrate 10 may be provided. The package substrate 10 may include a printed circuit board (PCB) including signal patterns on a top surface thereof. Alternatively, the package substrate 10 may have a structure, in which insulating layers and wiring layers are alternately stacked. The package substrate 10 may include pads, which are disposed on a top surface thereof.

Outer terminals 12 may be disposed below the package substrate 10. In detail, the outer terminals 12 may be formed on terminal pads, which are placed on a bottom surface of the package substrate 10. The outer terminals 12 may include solder balls or solder bumps, and the semiconductor package may be classified into a ball grid array (BGA) package, a fine ball-grid array (FBGA) package, or a land grid array (LGA) package, depending on the type and arrangement of the outer terminals 12.

An interposer substrate 100 may be provided on the package substrate 10. The interposer substrate 100 may have substantially the same or similar structure as the wiring substrate 100 described with reference to FIGS. 1 to 9. In the embodiment of FIG. 11, the wiring substrate of FIG. 7 is illustrated as an example of the interposer substrate 100. For example, the interposer substrate 100 may include the substrate protection layer 110, the substrate pads in the substrate protection layer 110, and the first substrate wiring layer RL1, the third substrate wiring layer RL3, and the second substrate wiring layer RL2, which are stacked on the substrate protection layer 110.

The substrate pads may include signal pads, ground pads, and power pads.

The first substrate wiring layer RL1 may include a first insulating pattern and first signal patterns, first ground patterns, a first power pattern, and fourth ground patterns, which are provided in the first insulating pattern. The first power pattern may be provided on the ground pads. The fourth ground patterns may be provided adjacent to the first power pattern. The fourth ground patterns may be placed between the first power pattern and the first signal patterns.

The third substrate wiring layer RL3 may have a third insulating pattern and a third ground pattern in the third insulating pattern. The third ground pattern may be placed on the first power pattern. The third ground pattern may cover the first power pattern.

The second substrate wiring layer RL2 may include a second insulating pattern and second signal patterns, second ground patterns, and second power patterns, which are provided in the second insulating pattern. At least some of the second signal patterns may be placed on the first power pattern. The third ground pattern may be provided to cross a region between the at least some of the second signal patterns and the first power pattern.

The interposer substrate 100 may further include an upper substrate protection layer 112, which is provided to cover the second substrate wiring layer RL2, and upper substrate pads 114, which are provided on the upper substrate protection layer 112.

The upper substrate protection layer 112 may include an insulating material. For example, the upper substrate protection layer 112 may be formed of or include an insulating polymer or a photoimageable dielectric (PID) material. The photoimageable dielectric material may include at least one of, for example, photoimageable polyimide, polybenzoxazole (PBO), phenol-based polymers, or benzocyclobutene-based polymers.

The upper substrate pads 114 may penetrate the upper substrate protection layer 112 and may be coupled to the second signal patterns, the second ground patterns, or the second power patterns of the second substrate wiring layer RL2.

The interposer substrate 100 may be mounted on a top surface of the package substrate 10. The substrate terminals 105 may be disposed on a bottom surface of the interposer substrate 100. The substrate terminals 105 may be provided between the pads of the package substrate 10 and the substrate pads of the interposer substrate 100. The substrate terminals 105 may electrically connect the interposer substrate 100 to the package substrate 10. For example, the interposer substrate 100 may be mounted on the package substrate 10 in a flip chip manner. The substrate terminals 105 may include solder balls or solder bumps.

A first under-fill layer 102 may be provided between the package substrate 10 and the interposer substrate 100. The first under-fill layer 102 may fill a space between the package substrate 10 and the interposer substrate 100 and may enclose the substrate terminals 105.

A chip stack may be disposed on the interposer substrate 100. The chip stack may include a base substrate, first semiconductor chips 820 stacked on the base substrate, and a first mold layer 830 enclosing the first semiconductor chips 820. Hereinafter, the structure of the chip stack will be described in more detail.

The base substrate may be a base semiconductor chip 810. For example, the base substrate may be a wafer-level semiconductor substrate that is formed of a semiconductor material (e.g., silicon (Si)). Hereinafter, the base semiconductor chip 810 may be the same element as the base substrate, and the base semiconductor chip and the base substrate may be identified using the same reference number.

The base semiconductor chip 810 may include a base circuit layer 812 and base penetration electrodes 816. The base circuit layer 812 may be provided on a bottom surface of the base semiconductor chip 810. The base circuit layer 812 may include an integrated circuit. For example, the base circuit layer 812 may be a memory circuit. That is, the base semiconductor chip 810 may be a memory chip (e.g., a DRAM, SRAM, MRAM, or FLASH memory chip). The base penetration electrodes 816 may be provided to penetrate the base semiconductor chip 810 in a direction perpendicular to a top surface of the interposer substrate 100. The base penetration electrodes 816 and the base circuit layer 812 may be electrically connected to each other. The bottom surface of the base semiconductor chip 810 may be an active surface. FIG. 11 illustrates an example, in which the base substrate includes the base semiconductor chip 810, but inventive concepts are not limited to this example. In an embodiment, the base substrate may not include the base semiconductor chip 810.

The base semiconductor chip 810 may further include a protection layer and first connection terminals 814. The protection layer may be disposed on the bottom surface of the base semiconductor chip 810 to cover the base circuit layer 812. The protection layer may be formed of or include silicon nitride (SiN). The first connection terminals 814 may be provided on the bottom surface of the base semiconductor chip 810. The first connection terminals 814 may be electrically connected to an input/output circuit (e.g., the memory circuit) of the base circuit layer 812. The first connection terminals 814 may be exposed from the protection layer.

The first semiconductor chip 820 may be mounted on the base semiconductor chip 810. That is, the first semiconductor chip 820 and the base semiconductor chip 810 may form a chip-on-wafer (COW) structure. A width of the first semiconductor chip 820 may be smaller than a width of the base semiconductor chip 810.

The first semiconductor chip 820 may include a first circuit layer 822 and first penetration electrodes 826. The first circuit layer 822 may include a memory circuit. For example, the first semiconductor chip 820 may be a memory chip (e.g., a DRAM, SRAM, MRAM or FLASH memory chip). The first circuit layer 822 may include the same circuit as the base circuit layer 812, but inventive concepts are not limited to this example. The first penetration electrodes 826 may penetrate the first semiconductor chip 820 in a direction that is perpendicular to the top surface of the interposer substrate 100. The first penetration electrodes 826 and the first circuit layer 822 may be electrically connected to each other. A bottom surface of the first semiconductor chip 820 may be an active surface. Chip bumps 824 may be provided on the bottom surface of the first semiconductor chip 820. The chip bumps 824 may be provided between the base semiconductor chip 810 and the first semiconductor chip 820 to electrically connect the base semiconductor chip 810 to the first semiconductor chip 820.

In an embodiment, a plurality of first semiconductor chips 820 may be provided. For example, a plurality of first semiconductor chips 820 may be stacked on the base semiconductor chip 810. The number of the first semiconductor chips 820 stacked may be 8 to 32. The chip bumps 824 may be provided between the first semiconductor chips 820. Here, the uppermost one of the first semiconductor chips 820 may not include the first penetration electrode 826. In addition, a thickness of the uppermost one of the first semiconductor chips 820 may be larger than a thickness of another one of the first semiconductor chips 820 thereunder.

Although not shown, an adhesive layer may be provided between the first semiconductor chips 820. The adhesive layer may include a non-conductive film (NCF). The adhesive layer may be interposed between the chip bumps 824 between the first semiconductor chips 820 to limit and/or prevent a short circuit from being formed between the chip bumps 824.

A first mold layer 830 may be disposed on a top surface of the base semiconductor chip 810. The first mold layer 830 may be provided to cover the base semiconductor chip 810 and enclose the first semiconductor chips 820. A top surface of the first mold layer 830 may be coplanar with a top surface of the uppermost one of the first semiconductor chips 820, and the uppermost one of the first semiconductor chips 820 may be exposed to the outside of the first mold layer 830. The first mold layer 830 may include an insulating polymer material. For example, the first mold layer 830 may be formed of or include an epoxy molding compound (EMC).

The chip stack of the afore-described structure may be provided. The chip stack may be mounted on the interposer substrate 100. For example, the chip stack may be coupled to the upper substrate pads 114 of the interposer substrate 100 through the first connection terminals 814 of the base semiconductor chip 810. The first connection terminals 814 may be provided between the upper substrate pads 114 of the interposer substrate 100 and the base circuit layer 812.

A second under-fill layer 806 may be provided between the interposer substrate 100 and the chip stack. The second under-fill layer 806 may fill a space between the interposer substrate 100 and the base semiconductor chip 810 and may enclose the first connection terminals 814.

A second semiconductor chip 700 may be disposed on the interposer substrate 100. The second semiconductor chip 700 may be spaced apart from the chip stack. The second semiconductor chip 700 may be thicker than the first semiconductor chips 820. The second semiconductor chip 700 may include a semiconductor material (e.g., silicon (Si)). The second semiconductor chip 700 may include a second circuit layer 702. The second circuit layer 702 may include a logic circuit. In other words, the second semiconductor chip 700 may be a logic chip. A bottom surface of the second semiconductor chip 700 may be an active surface, and a top surface of the second semiconductor chip 700 may be an inactive surface. Second connection terminals 704 may be provided on the bottom surface of the second semiconductor chip 700. The second connection terminals 704 may be electrically connected to an input/output circuit (e.g., the logic circuit) of the second circuit layer 702.

The second semiconductor chip 700 may be mounted on the interposer substrate 100. For example, the second semiconductor chip 700 may be coupled to the upper substrate pads 114 of the interposer substrate 100 through the second connection terminals 704. The second connection terminals 704 may be provided between the upper substrate pads 114 of the interposer substrate 100 and the second circuit layer 702.

A third under-fill layer 706 may be provided between the interposer substrate 100 and the second semiconductor chip 700. The third under-fill layer 706 may fill a space between the interposer substrate 100 and the second semiconductor chip 700 and may enclose the second connection terminals 704.

A second mold layer 900 may be provided on the interposer substrate 100. The second mold layer 900 may cover the top surface of the interposer substrate 100. The second mold layer 900 may enclose the chip stack and the second semiconductor chip 700. The second mold layer 900 may include an insulating material. For example, the second mold layer 900 may include an epoxy molding compound (EMC).

In a wiring substrate according to an embodiment of inventive concepts and a semiconductor package including the same, a first power pattern and ground pads may be provided to form a micro strip structure, or the ground pad, the first power pattern, and a third ground pattern may be provided to form a strip line structure. Thus, an interference (e.g., noise) signal, which is generated from the first power pattern, may be absorbed by the ground pads. Accordingly, it may be possible to limit and/or prevent the interference signal, which is generated from the first power pattern, from affecting signal pads or other patterns (e.g., first signal patterns) in a first substrate wiring layer. That is, the wiring substrate and the semiconductor package therewith may have improved electrical characteristics.

In addition, even when second signal patterns are placed on the first power pattern, the ground pads may absorb the interference signal, which is generated from the first power pattern, and thus, the second signal patterns may not be affected by the interference signal. Accordingly, even when the first power pattern is disposed to cross a region between the signal pads or the first signal patterns or is disposed to overlap with the second signal patterns, the interference signal may not affect operation signals of the signal pads, the first signal patterns, and the second signal patterns. Thus, there is no need to dispose the first power pattern in an edge region of a wiring substrate to bypass the signal pads, the first signal patterns, and the second signal patterns. In other words, it may be possible to improve the electrical characteristics of the wiring substrate, increase a degree of freedom in disposing a wiring structure in the wiring substrate, and reduce sizes of the wiring substrate and the semiconductor package.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While example embodiments of inventive concepts have been particularly shown and described, it will be understood by one of ordinary skill in the art that variations in form and detail may be made therein without departing from the spirit and scope of the attached claims.

What is claimed is:

1. A wiring substrate, comprising:
a first substrate wiring layer including a first insulating pattern and a power pattern in the first insulating pattern;
a second substrate wiring layer on the first substrate wiring layer, the second substrate wiring layer including a second insulating pattern and a first ground pattern in the second insulating pattern;
a third substrate wiring layer on the second substrate wiring layer, the third substrate wiring layer including a third insulating pattern and a first signal pattern in the third insulating pattern; and
a pad layer covering a bottom surface of the first substrate wiring layer, the pad layer including a protection layer and the pad layer including signal pads and a ground pad in the protection layer, wherein
the ground pad is between the signal pads,
the power pattern vertically overlaps the ground pad,
the first ground pattern vertically overlaps the ground pad and the power pattern, and
the first signal pattern is on the first ground pattern.

2. The wiring substrate of claim 1, wherein
the first substrate wiring layer further comprises a second ground patterns,
the power pattern is between the second ground patterns, and
the second ground patterns are spaced apart from the power pattern with the first insulating pattern in between.

3. The wiring substrate of claim 2, wherein
the first substrate wiring layer further comprises a second signal pattern, and
at least one of the second ground patterns are between the power pattern and the second signal pattern.

4. The wiring substrate of claim 1, wherein
the power pattern vertically overlaps the first signal pattern, and
the first ground pattern crosses a region between the first signal pattern and the power pattern.

5. The wiring substrate of claim 1, wherein
on the ground pad, a horizontal width of the power pattern is 0.8 to 1.2 times a horizontal width of the ground pad.

6. The wiring substrate of claim 1, wherein
the power pattern is between the signal pads, when viewed in a plan view.

7. The wiring substrate of claim 1, wherein
the ground pad is on a center region of the pad layer,
the signal pads are on an edge region of the pad layer, and
the edge region of the pad layer encloses the center region of the pad layer.

8. The wiring substrate of claim 1, wherein
on the ground pad, side surfaces of the power pattern in a width direction are on the ground pad.

9. A wiring substrate, comprising:
a body layer;
a ground pad and signal pads on a bottom surface of the body layer;
a first substrate wiring layer in the body layer; and
a second substrate wiring layer in the body layer and on the first substrate wiring layer, wherein
the first substrate wiring layer comprises first signal patterns and a power pattern,
the power pattern is placed between the first signal patterns, when viewed in a plan view,
the power pattern is placed on the ground pad,
the second substrate wiring layer comprises a second signal pattern, and
the second signal pattern is on the power pattern.

10. The wiring substrate of claim 9, further comprising:
a third substrate wiring layer in the body layer and between the first substrate wiring layer and the second substrate wiring layer, wherein
the third substrate wiring layer comprises a first ground pattern, and
the first ground pattern is crosses a region between the power pattern and the second signal pattern.

11. The wiring substrate of claim 9, wherein
side surfaces of the power pattern in a width direction are on the ground pad.

12. The wiring substrate of claim 9, wherein
the first substrate wiring layer further comprises ground patterns, and
the ground patterns are between the power pattern and the first signal patterns.

13. The wiring substrate of claim 9, wherein a horizontal width of the power pattern on the ground pad is 0.8 to 1.2 times a horizontal width of the ground pad.

14. The wiring substrate of claim 9, wherein
the ground pad is between the signal pads, when viewed in the plan view.

15. The wiring substrate of claim 9, wherein at least a portion of the second signal pattern overlaps the power pattern.

16. A semiconductor package, comprising:
a substrate;
a semiconductor chip on the substrate; and
a mold layer on the substrate and enclosing the semiconductor chip, wherein
the substrate includes a body layer, a ground pad and signal pads on a bottom surface of the body layer, a first signal pattern in the body layer, and a power pattern in the body layer,
the power pattern is between the ground pad and the first signal pattern,
the power pattern is on the ground pad,
the first signal pattern is on the power pattern, and
on the ground pad, a horizontal width of the power pattern is 0.8 to 1.2 times a horizontal width of the ground pad.

17. The semiconductor package of claim 16, further comprising:
a first ground pattern in the body layer and crossing a region between the power pattern and the first signal pattern, wherein
a width of the power pattern is smaller than a width of the first ground pattern.

18. The semiconductor package of claim 16, further comprising:
second ground patterns in the body layer at the same vertical level as the power pattern, wherein
the power pattern is between the second ground patterns.

19. The semiconductor package of claim 16, wherein,
on the ground pad, side surfaces of the power pattern in a width direction are on the ground pad.

20. The semiconductor package of claim 16, further comprising:
second signal patterns in the body layer and at the same vertical level as the power pattern, wherein
the power pattern is placed between the second signal patterns.
